(19) United States
(12) Patent Application Publication
(10) Pub. No.: US 2026/0016521 A1
(43) Pub. Date: Jan. 15, 2026

(54) DIRECT CURRENT (DC) INSULATION MONITORING USING VOLTAGE DECAY PREDICTIONS

(71) Applicant: TEXAS INSTRUMENTS INCORPORATED, Dallas, TX (US)

(72) Inventors: Sophie CZELUSTA, Houston, TX (US); Kelvin LE, Richardson, TX (US)

(21) Appl. No.: 19/098,461

(22) Filed: Apr. 2, 2025

Related U.S. Application Data
(60) Provisional application No. 63/671,721, filed on Jul. 15, 2024.

(51) Int. Cl. G01R 27/02; G01R 27/26

(52) U.S. Cl. CPC G01R 27/025; G01R 27/2605

(57) ABSTRACT

A system, computer readable program product, and associated processes include a charging device cable of being coupled to a power supply rail, where the charging device includes a controller cable of: receiving a plurality of voltage measurements of a voltage discharge of a capacitor that is positioned between a power supply rail and ground, determining a predicted settling voltage based on the plurality of voltage measurements, where the predicted settling voltage is a voltage level at which the voltage discharge is predicted to stabilize, and outputting an insulation resistance present between the power supply rail and the ground. The system further includes a load capable of receiving power from the charging device.

### CROSS-REFERENCE TO RELATED APPLICATIONS

The present application claims priority to U.S. Provisional Patent Application No. 63/671,721, which was filed Jul. 15, 2024, is titled “DC RESISTOR BRIDGE INSULATION MONITORING BY VOLTAGE DECAY PREDICTION IN HIGH-VOLTAGE DC EV CHARGING AND SOLAR ENERGY,” and is hereby incorporated herein by reference in its entirety.

### BACKGROUND

High power isolated DC power supplies use insulation monitors for user safety. Insulation monitoring involves determining an insulation resistance between power lines and earth ground. These power supplies often include safety Y-capacitors (Y-caps) to filter the power supply common-mode noise. However, having large Y-caps can delay measurement time and reduce the accuracy of the measured insulation resistance.

### SUMMARY

In at least one example, a system includes a charging device cable of being coupled to a power supply rail, where the charging device includes a controller cable of: receiving a plurality of voltage measurements of a voltage discharge of a capacitor that is positioned between a power supply rail and ground, determining a predicted settling voltage based on the plurality of voltage measurements, where the predicted settling voltage is a voltage level at which the voltage discharge is predicted to stabilize, and outputting an insulation resistance present between the power supply rail and the ground. The system further includes a load capable of receiving power from the charging device.

In another example, an apparatus includes a power supply rail capable of being coupled to a power source, and a controller capable of: receiving a plurality of voltage measurements of a voltage discharge of a capacitor that is positioned between the power supply rail and a ground, determining a time constant of the capacitor based on plurality of voltage measurements, determining a capacitance of the capacitor based on the time constant, and outputting the capacitance.

Other examples include a computer program product to monitor an insulation resistance of a power supply circuit, the computer program product including a computer-readable storage medium having computer-readable program code embodied therewith, the computer-readable program code to be executed by a controller to: receive a plurality of voltage measurements of a voltage discharge of a capacitor that is positioned between a power supply rail and ground; determine a predicted settling voltage based on the plurality of voltage measurements, where the predicted settling voltage is a voltage level at which the voltage discharge is predicted to stabilize; and output an insulation resistance present between the power supply rail and the ground.

### BRIEF DESCRIPTION OF THE DRAWINGS

FIG. 1 is a schematic diagram of an implementation of a power supply system that includes an insulation monitoring circuit configured to receive voltage measurements comprising the voltage discharge of capacitors that are positioned between power supply rails and ground in various examples.

FIG. 2 is a graph depicting a voltage discharge curve representative of a voltage discharge of a Y-type capacitor over time used to determine a steady state voltage with various examples.

FIG. 3 is a circuit diagram of an implementation of a voltage divider circuit that includes isolated voltage divider branches to periodically and selectively switch between one of the first and second power supply rails and the chassis ground to determine the insulation resistance based, in part, on measured and predicted voltage values, with various examples.

FIG. 4 is an electrical circuit diagram of an isolated first (e.g., positive) voltage branch of a first supply rail when a controller opens the first switch and closes the second switch of an insulation monitoring circuit to receive voltage measurements with various examples.

FIG. 5 is an electrical circuit diagram of an isolated, second voltage branch of the second (e.g., negative) supply rail when the controller opens the first switch and closes the second switch of the insulation monitoring circuit to receive voltage measurements with various examples.

FIG. 6 is a block diagram of an example of an electrical vehicle (EV) power supply system configured to monitor the insulation resistance of a power supply system that includes Y-type capacitors with various examples.

FIG. 7 is a flowchart of an example of a method to monitor the insulation resistance of a power supply system that includes Y-type capacitors with various examples.

### DETAILED DESCRIPTION

Y-type capacitors are typically positioned between a direct current (DC) power supply and a chassis ground in charging operations to filter out common-mode noise. Also known as line to ground, or line bypass capacitors, Y-type capacitors filter noise currents by allowing them to return to ground, thus completing a circuit. While effective filters, Y-type capacitors have their own safety considerations. Namely, Y-type capacitors are designed to fail open-circuit. The resultant short in the circuit presents a shock hazard to personnel and connected circuitry. As such, applications that rely on Y-type capacitors, such as solar power and electronic vehicle (EV) fleet charging operations, use insulation monitoring techniques to facilitate their safe operation. For instance, direct current (DC) EV chargers use insulation monitoring to measure insulation resistance.

Insulation monitoring is a safety technique that measures the resistance between a high voltage system and its chassis ground. As such, an insulation monitoring circuit is connected between live supply conductors and ground. Thus positioned, the insulation monitoring circuit superimposes a measuring voltage, or voltage drop. The insulation monitoring circuit uses the measured voltage to determine the insulation resistance of a system. The insulation resistance measurement may include the aggregated resistances of capacitors, as well as for other connected devices (e.g., a voltage sensing circuit) that are parallel to the capacitor. Put another way, the insulation resistance of an implementation is a measure of the resistance present between a power supply unit (PSU) (e.g., and associated power supply rails) and ground.

The insulation monitoring system initiates a shutdown if the insulation resistance is insufficient. Put another way, if the voltage drop exceeds a certain value, insulation monitoring outputs a signal to indicate an insulation fault. In this manner, insulation monitoring circuits serve as early-warning systems, providing operators with the information to implement appropriate maintenance measures.

Insulation monitoring can be impeded by the presence of Y-type capacitors. Y-type capacitors can have relatively lengthy time constants. A time constant is the time it takes for Y-type capacitors to be charged to an industry accepted percentage (e.g., 63.2%) of their full charge. This time constant can be too long for conventional insulation monitoring. For instance, insulation monitoring might need to be completed within two seconds, which is quicker than the time constant of some Y-type capacitors. As a result, an output voltage (e.g., between the high voltage system and its chassis) sensed by the insulation monitoring will not have enough time to determine a viable measurement value within the available measurement time.

An implementation uses an isolated resistor divider branch that is periodically switched between each power supply rail and chassis ground. The voltage across the divider initially spikes, then settles to a lower value as the Y-type capacitors discharge. This settling voltage is used in combination with the determined resistor divider values and the source voltage to determine the insulation resistance on a power supply rail. The processes are repeated for the other power supply rail.

As alluded to above, the Y-type capacitors include a time constant that equals resistance times capacitance. This time constant can last several seconds, during which a fault or fluctuation in insulation could cause safety issues that go unmonitored. In other words, the insulation monitoring may not be able to determine requisite resistance values (and the presence of a fault) within the allotted two second time window.

Implementations receive a plurality of voltage measurements of a voltage discharge of a capacitor that is positioned between a power supply rail and ground. Examples determine a predicted settling voltage based on the plurality of voltage measurements. The predicted settling voltage is a voltage level at which the voltage discharge is predicted to stabilize. A controller outputs an insulation resistance measurement of the system.

The insulation resistance measurement is used to provide insulation monitoring for devices, such as DC chargers and solar energy equipment that have Y-type capacitances that approach or exceed microfarads or millifarads in scale. The predicted insulation measurement enables faster measurement times while maintaining the accuracy of the insulation measurement. Examples thus provide a cost-effective method of measuring the insulation resistance. The measurement is accomplished in scenarios where Y-type capacitors would otherwise impede accurate and efficient measurement. For example, an implementation is effective for Y-type capacitance values and can accurately monitor symmetric and asymmetric (e.g., insulation) faults with reduced measurement time. In symmetric measuring, the same insulation resistance is present on both power supply rails. Asymmetric measuring occurs when only one power supply rail is working, and the other is faulty or otherwise unbalanced.

Monitoring the insulation resistance in some examples described herein takes less than two seconds to measure time for a 10 microfarad Y-type capacitor. Other benefits include cost-effectively supplying power to isolated switches and voltage sense components. This feature reduces size, complexity, and cost, particularly compared to AC injection methods of insulation monitoring. An implementation may be tuned to different accuracies at specific insulation warning and fault values for specific applications. For example, different voltage, resistance, and/or capacitance levels may be selected as thresholds that initiate a warning signal. Moreover, implementations use four-function arithmetic (e.g., addition, subtraction, multiplication, and/or division). The relatively simplistic arithmetic reduces processing requirements. Bus voltage is constantly monitored for improved accuracy that accounts for bus voltage fluctuations.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

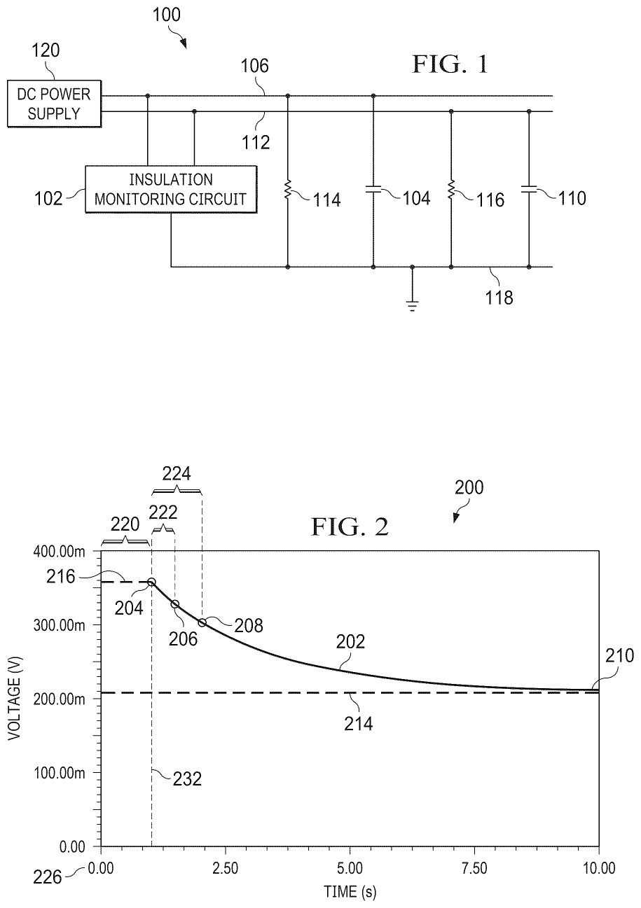

FIG. 1 is a schematic diagram of an implementation of a power supply system 100 that includes an insulation monitoring circuit 102 that receives voltage measurements comprising a voltage discharge of a first capacitor 104. The first capacitor 104 is positioned between a first power supply rail 106 and ground 118. The insulation monitoring circuit 102 determines a predicted settling voltage based on the plurality of voltage measurements. The insulation monitoring circuit 102 further outputs an insulation resistance measurement of the first capacitor 104 for monitoring. As described herein, the predicted settling voltage is a voltage level at which the voltage discharge of the first capacitor 104 is predicted to stabilize.

FIG. 1 more particularly shows the first capacitor 104 that is positioned between the first power supply rail 106 and ground 118 of the power supply system 100. The insulation monitoring circuit 102 is coupled between the first power supply rail 106 and ground 118. A second capacitor 110 is positioned between a second power supply rail 112 and ground 118. In some examples, the first and second capacitors 104, 110 are Y-type capacitors positioned between a DC supply 120 and the (e.g., chassis) ground 118 to filter out common-mode noise. The insulation monitoring circuit 102 is additionally coupled between the second power supply rail 112 and ground 118. A first resistor 114, which represents the insulation resistance, is shown between the first power supply rail 106 and ground 118. A second resistor 116, which is also representative of insulation resistance, is shown between the second power supply rail 112 and ground 118. In the specific example of an EV power supply system, the insulation monitoring circuit 102 and/or the capacitors 104, 110 may be positioned in either or both of the EV or the device charging the EV.

The insulation monitoring circuit 102 additionally receives second voltage measurements of a voltage discharge of the second capacitor 110, which is positioned between the second power supply rail 112 and ground 118. The first and second capacitors 104, 110 filter noise currents, as described herein. The insulation monitoring circuit 102 determines a second predicted settling voltage based on second voltage measurements. The second predicted settling voltage is a voltage level at which the voltage discharge of the second capacitor 110 is predicted to stabilize. The insulation monitoring circuit 102 further outputs a second insulation resistance measurement of the second capacitor 110 for monitoring.

As described in greater detail below, the first and second voltage measurements each include voltage values sensed at three different times along the output voltage curve of the corresponding first and second capacitors 104, 110. The three points correspond to three unknowns in the voltage response. The insulation monitoring circuit 102 uses four-function arithmetic to predict a final voltage. The insulation monitoring circuit 102 uses the predicted final voltage to determine one of the corresponding insulation resistance values.

The insulation monitoring circuit 102 thus promotes safe operation by monitoring the insulation resistance. More particularly, the insulation monitoring circuit 102 initiates a shutdown if the insulation resistance is insufficient. As described herein, if the voltage drop exceeds a preset value, the insulation monitoring circuit 102 outputs a signal to indicate an insulation fault. Using four-function arithmetic allows the processing to be simplified and permits a wider range of relatively less expensive controllers to be used. Implementations of the insulation monitoring circuit 102 allow monitoring in the presence of Y-type and other capacitors that have time constants that exceed the window in which conventional insulation monitoring techniques must be performed.

FIG. 2 is a graph 200 depicting a voltage discharge curve 202 representative of a voltage discharge of a Y-type capacitor over time. Implementations use the voltage discharge of the capacitors to determine a steady state voltage. As described herein, the steady state voltage is used to determine the resistance of the insulation. The voltage may be discharged from either the first capacitor 104 or the second capacitor 110 of FIG. 1. Three or more voltage values 204, 206, 208 are measured along the voltage discharge curve 202. As shown in FIG. 2, the voltage discharge curve 202 decays exponentially as the Y-capacitor discharges. This exponential decay and the voltage values 204, 206, 208 are leveraged to predict a settling voltage value 214 (e.g., final output) as time 210 approaches infinity. This settling voltage value 214 is used in conjunction with the determined resistor divider values and the source voltage to calculate the insulation resistance on one side (e.g., on one power supply rail).

As illustrated, the capacitor output voltage is sensed at three points along the voltage discharge curve 202. The three points (i.e., voltage values 204, 206, 208) correspond to three unknowns in the voltage response. Measured from when the initial, first voltage value 204 is taken, the interval 222 spans to when the second voltage value 206 is measured. The interval 222 is half as long as an interval 224 measured from the initial measurement to when the third voltage value 208 is measured. Put another way, the interval 224 is twice as long as the interval 222.

The time of the measurement of the first voltage value 204 does not have to be at time zero 226. The initial measurement can be another time along the curve 202 so long as the time between when the first and second measurements (e.g., voltage values 204 and 206) are taken is equal in length to the time between when the second and third measurements (e.g., voltage values 206 and 208) are taken. That is, the interval 224 spanning between the first and third voltage measurements (e.g., voltage values 204, 208) is twice as long as the interval 222 spanning between the first and second voltage measurements (e.g., voltage values 204, 206). The measurement intervals facilitate the collapse of the equations into simpler equations to avoid the necessity of floating-point format and exponential logarithmic computations. This feature reduces computational costs for processing resources considerations.

A controller uses four-function arithmetic to predict the settling voltage 214. The controller uses the predicted final voltage to determine one of the corresponding insulation resistance values. Put another way, the predicted settling voltage 214 is automatically determined by inputting voltage values 204, 206, 208 into a voltage discharge algorithm.

More particularly, the predicted settling voltage

$$( {V}_{inf} ) = \frac{V ( 0 ) * V ( {t}_{2} ) - {V ( {t}_{1} )}^{2}}{V ( 0 ) - 2 V ( {t}_{1} ) + V ( {t}_{2} )} .$$

In the preceding equation, and in terms of FIG. 2, V_{inf} is the settling voltage 214; V(0) is the voltage value 204; V(t1) is the voltage value 206, and V(t2) is the voltage value 208.

The settling voltage 214, or steady state voltage, is used to determine the resistance of the insulation. That is, the settling voltage 214 is transmitted as an input for further processing by the insulation monitoring circuit to determine the insulation resistance for the power supply rail, as described below. If the insulation resistance drop is determined to be high compared to a preset threshold, then an alert is automatically generated to indicate a short circuit. Additionally, the predicted settling voltage 214 and other curve fitting processes may be used to predict the insulation capacitance of the power supply system based on the voltage decay. Predicting the insulation capacitance is useful for determining the working condition (e.g., aging characteristics) of a capacitor for taking preemptive maintenance action.

The curve fitting processes reduce processing cycles and associated hardware expenses. Processes further reduce hardware space requirements and power consumption compared to processing resources used in AC injection monitoring. By using curve fitting, the system uses the predicted settling voltage to accurately determine the insulation resistance for a power supply rail.

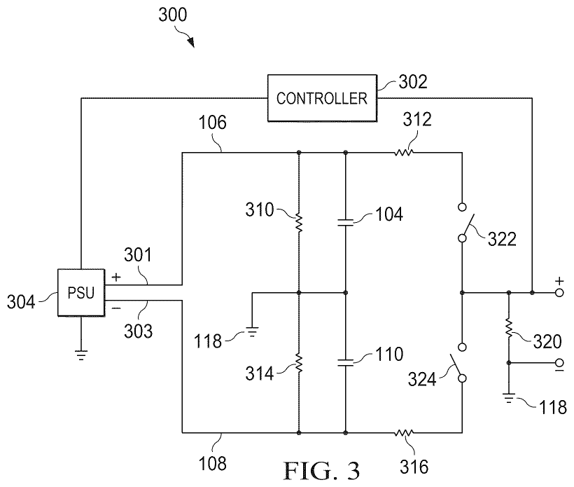

FIG. 3 is a circuit diagram of an implementation of a voltage divider voltage divider circuit 300 that includes isolated voltage divider branches to periodically and selectively switch between one of the first and second power supply rails 106, 108 and the chassis ground 118. The circuit 300 determines the insulation resistance based, in part, on measured and predicted voltage values.

The voltage divider circuit 300 includes a first voltage branch 301 and a second voltage branch 303. The first voltage branch 301 is coupled to a first power supply rail 106 (i.e., the positive power supply rail) and includes a first resistor 310 and a second resistor 312 coupled in series. The first capacitor 104 is coupled in parallel to the first resistor 310. The second voltage branch 303 is coupled to the second power supply rail 108 (i.e., the negative power supply rail) and includes a third resistor 314 and a fourth resistor 316 coupled in series. The second capacitor 110 is coupled in parallel to the third resistor 314.

A controller 302 is coupled to both the negative and positive power supply rails 106, 108 and a power supply unit 304. In the specific example of an EV power supply system, the insulation monitoring circuit 102 and/or the capacitors 104, 110 may be positioned in either or both of an EV or the device charging the EV.

A first switch 322 is coupled to the first voltage branch 301, and a second switch 324 is coupled to the second voltage branch 303. Switches 322, 324 of examples comprise solid state relays (SSRs). When measuring voltage values for the first (e.g., positive) supply rail 106, the controller 302 closes the first switch 322 and opens the second switch 324 while receiving the plurality of voltage measurements (e.g., the voltage values 204, 206, 208 of FIG. 2). When measuring voltage values for the second (e.g., negative) supply rail 108, the controller 302 closes the first switch 322 and opens the second switch 324 while receiving the plurality of voltage measurements (e.g., the voltage values 204, 206, 208 of FIG. 2). When one of the switches 322 or 324 is closed, the corresponding voltage branch 301 or 303, respectively, includes a fifth resistor 320 that is coupled to ground 118. The fifth resistor 320 is coupled to terminals 326, 328. The terminals 326, 328 may connect to, for instance, an isolated amplifier and an analog-to-digital converter of the controller. An oscilloscope can be used to sample an output of the analog-to-digital converter to provide an indication of the timing patterns of the algorithms described herein.

The voltage across the voltage divider circuit 300 initially spikes due to the first and second capacitors 104, 110, and then the voltage settles to a lower value as the capacitors 104, 110 discharge. This settling voltage is used in conjunction with the determined resistor divider values and the source voltage to calculate the insulation resistance on one side (e.g., on one power supply rail 106 or 108).

Using the predicted settling voltage as an input, the insulation resistance of the first supply rail 106 is determined by the controller 302 according to:

$${R}_{isoP} = \frac{- ( {R}_{st} + {R}_{inAMC} ) \times ( {V}_{DC} + {V}_{N} - {V}_{P} )}{{V}_{N}} ,$$

where R_{isoP} is the insulation resistance of the first power supply rail 106; Rₛₜ is the value of the resistor 312; R_{inAMC} is the value of the resistor 320; V_{DC} is the voltage at the PSU 304, and

$${V}_{P} = {V}_{infP} \times \frac{{R}_{stP} + {R}_{inAMC}}{{R}_{inAMC}} ,$$

where V_{infP} is the settling voltage for the first power supply 106, and

$${V}_{N} = {v}_{infN} \times \frac{{R}_{stN} + {R}_{inAMC}}{{R}_{inAMC}} ,$$

where V_{infN} is the settling voltage for the second power supply rail 108, and RₛₜN is the value of the resistor 316. R_{stN}=R_{stP}=Rₛₜ. The insulation resistance of the second power supply rail is determined by the controller 302 according to:

$${R}_{isoN} = \frac{( {R}_{st} + {R}_{inAMC} ) \times ( {V}_{DC} + {V}_{N} - {V}_{P} )}{{V}_{P}} .$$

As described herein, the predicted settling voltage 214 and other curve fitting processes may be used to predict, or estimate, the insulation capacitance of the power supply system based on the voltage decay. Predicting the insulation capacitance is useful for determining the working condition of a capacitor and for related maintenance considerations. To this end, the controller 302 determines a time constant of the capacitor by calculating a derivative of a discharge curve at the time that voltage value 204 is taken. In terms of FIG. 2, the controller 302 determines the time constant (t) for the first power supply rail 106 (e.g., and capacitor 104) by taking the first derivative of the voltage value 204 at time 232. The derivative finds the slope of the voltage discharge curve 202 at time 232 at the measurement point of the voltage value 204.

Once the time constant is determined, the system determines the insulation capacitance on a power supply line by dividing the time constant by the system resistance. The system resistance includes newly determined insulation resistances. As such, the insulation capacitance of the first power supply system is based on the first and second resistance measurements. More particularly, the insulation capacitance for the first power supply rail 106 is determined according to: Cᵢₛₒ=τ/(R_{isoP}∥R_{isoN}∥Rₛₜ), where Cᵢₛₒ is the insulation capacitance; τ is the time constant for the capacitor 104, R_{isoP} is the predicted insulation resistance of the first power supply rail 106; R_{isoN} is the predicted insulation resistance of the second power supply rail 108, and Rₛₜ is the value of the resistor 312.

For the second power supply rail 108, the controller 302 determines the insulation capacitance (Cᵢₛₒ) using the capacitor 110 according to: Cᵢₛₒ=τ/(R_{isoP}∥R_{isoN}∥Rₛₜ), where Cᵢₛₒ is the insulation capacitance; τ is the time constant for the capacitor 110, R_{isoP} is the predicted insulation resistance of the first power supply rail 106; R_{isoN} is the predicted insulation resistance of the second power supply rail 108, and Rₛₜ is the value of the resistor 316.

By alternating the switching in the positive and negative voltage branches 301, 303, implementations enable both symmetric and asymmetric measurements. In symmetric measuring, the same insulation resistance is present on both power supply rails. Asymmetric measuring occurs when only one power supply rail is working, and the other is faulty or otherwise unbalanced. The periodic switching thus facilitates robust and comprehensive short circuit detection.

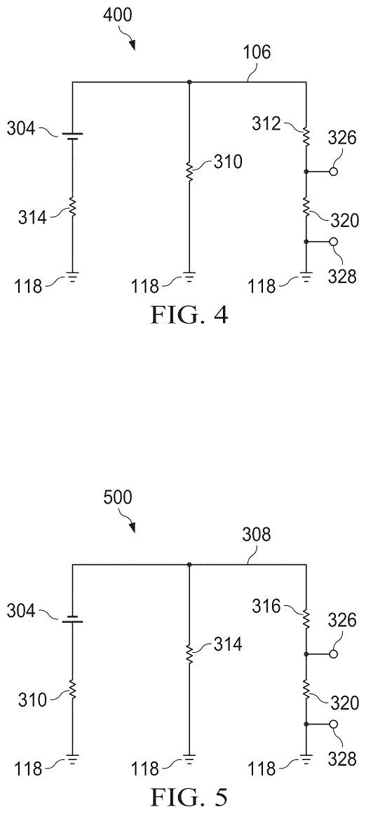

FIG. 4 is an electrical circuit diagram of an isolated first (e.g., positive) voltage branch 400 of the first supply rail 106 when the controller opens the first switch and closes the second switch of an insulation monitoring circuit to receive voltage measurements. For example, the first voltage branch 400 is depicted with the switch 322 of FIG. 3 being closed and the switch 324 being open. As such, the first voltage branch 400 is configured to measure the isolated voltage drop of the first supply rail 106.

The first voltage branch 400 is isolated by the switching operation to include the third resistor 314 branching from second supply rail 112. The third resistor 314 is in series with the voltage of the PSU 304, which is connected to ground 118. In parallel, the first resistor 310 is positioned between the first supply rail 106 and ground 118. The second resistor 312 and the fifth resistor 320 are connected in series between the first supply rail 106 and ground 118.

FIG. 5 is an electrical circuit diagram of an isolated second voltage branch 500 of the second (e.g., negative) supply rail 108 when the controller opens the first switch 322 and closes the second switch 324 of an insulation monitoring circuit to receive voltage measurements. For example, the second voltage branch 500 is depicted as when the switch 324 of FIG. 3 is closed and the switch 322 is open. As such, the second voltage branch 500 is configured to measure the isolated voltage drop of the second supply rail 108.

The second voltage branch 500 is isolated by the switching operation to include the first resistor 310 branching from the first supply rail 106. The first resistor 310 is in series with the voltage of the PSU 304, which is connected to ground 118. In parallel, the third resistor 314 is positioned between the second supply rail 108 and ground 118. The fourth resistor 316 and the fifth resistor 320 are connected in series between the second supply rail 108 and ground 118.

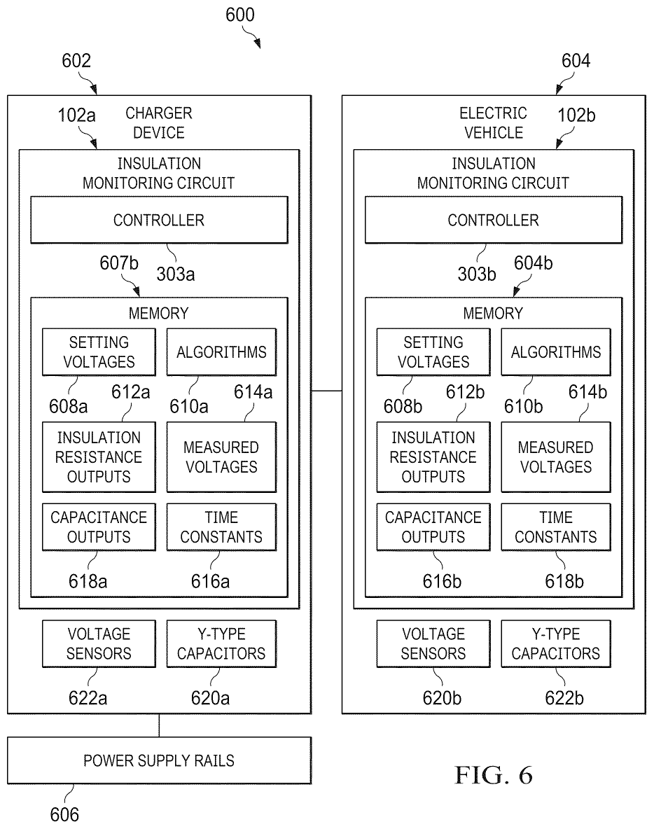

FIG. 6 is a block diagram of an example of an EV power supply system 600 configured to monitor the insulation resistance of a power supply system that includes Y-type capacitors. The EV power supply system 600 includes a charger device 602 that is coupled to an EV 604 and to power supply rails 606.

In the implementation, the charger device 602 includes an insulation monitoring circuit 102a having a controller 303a and a memory 607a. The charger device 602 further includes Y-type capacitors 622a, as well as voltage sensors 620a to make voltage measurements of the voltage discharge of the capacitors 622a.

The memory 607a includes stored settling voltages 608a, algorithms 610a, and insulation resistance outputs 612a. The memory 607a further includes stored measured voltages 614a, capacitance outputs 616a, and time constants 618a.

As shown, the EV 604 includes an insulation monitoring circuit 102b having a controller 303b and a memory 607b. The EV 604 further includes Y-type capacitors 622b, as well as voltage sensors 620b to make voltage measurements of the voltage discharge of the capacitors 622b.

The memory 607b includes stored settling voltages 608b, algorithms 610b, and insulation resistance outputs 612b. The memory 607b further includes stored measured voltages 614b, capacitance outputs 616b, and time constants 618b.

Although an EV power supply system 600 is shown, other examples may include other types of DC chargers and solar energy equipment having Y-type capacitances that approach or exceed microfarads or millifarads in scale. Faster measurement times while maintaining the accuracy of the measured insulation resistance. Examples thus provide a cost-effective method of measuring the insulation resistance. The measurement is accomplished in scenarios where Y-type capacitors would otherwise impede accurate and efficient measurement. Moreover, while the illustrated EV power supply system 600 include similar or duplicate functional components in each of the charger device 602 and EV 604, another example may include comparable functional components in only one of the charger devices 602 or EV 604, or portions of the functionalities may be shared or otherwise distributed between them.

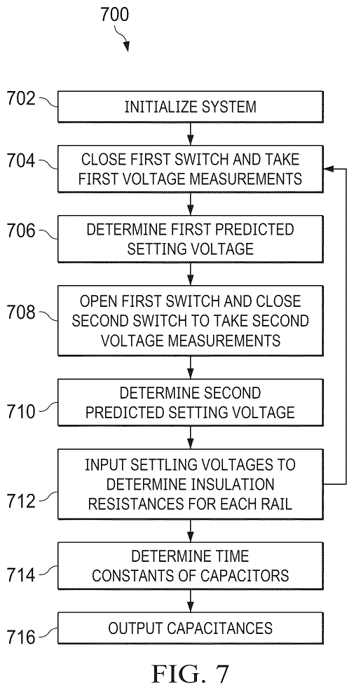

FIG. 7 is a flowchart of an example of a method 700 to monitor the insulation resistance in a power supply system that includes Y-type capacitors. The illustrative method 700 may be performed by any of the preceding systems of FIG. 1 or 3-6. As with other diagrams included herein, additional blocks may be included, and included blocks may be omitted or rearranged per the specific implementations contemplated within this description.

Turning more particularly to flowchart, the method 700 includes initializing the system at block 702. Initialization processes may include receiving the PSU voltage measurement and resistor inputs at the controller. The method 700 further includes closing a first switch at block 704 (while a second switch remains open) to take first voltage measurements. For instance, when measuring voltage values for the first (e.g., positive) supply rail 106 in the system of FIG. 3, the controller 302 closes the first switch 322 and opens the second switch 324 while receiving voltage measurements.

At block 706, the method 700 includes determining a first settling voltage. For example, the predicted settling voltage 214 of FIG. 2 is automatically determined by inputting voltage values 204, 206, 208 into a predetermined capacitor discharge algorithm.

The method 700 may include opening the first switch at block 708 and closing the second switch to take second voltage measurements. For instance, when measuring voltage values for the second (e.g., negative) supply rail 108, the controller 302 opens the first switch 322 and closes the second switch 324 while receiving a second plurality of voltage measurements. The method 700 uses the second voltage measurements at block 710 to determine a second predicted settling voltage.

At block 712, the method 700 uses the predicted settling voltages (e.g., determined at blocks 706 and 710) to determine at block 712 an insulation resistance for the each of the first and second power supply rails. For example, the voltage divider circuit 300 of FIG. 3 uses the predicted settling voltage in combination with determined resistor divider values and the source voltage to calculate the insulation resistance on one side (e.g., either supply rail 106 or 108). The method 700 loops back from block 712 to block 704 to continuously monitor the insulation resistances.

At block 714, the method 700 includes determining a time constant of the capacitor by calculating a derivative of a point along the voltage discharge curve. Once the time constant is determined block 714, the method 700 determines and outputs the insulation capacitance at block 716 by dividing the time constant by the system resistance.

In this manner, the processes of the method 700 enable effective monitoring of the insulation resistances in systems having Y-type capacitors. Moreover, processes use four-function arithmetic that reduces processing requirements. Bus voltage is continuously monitored for improved accuracy to account for bus voltage fluctuations.

Implementations of the method 700 may be performed by a controller executing computer-readable instructions. Computer-readable instructions and/or data can be stored on storage, such as storage/memory and/or the datastore. The term “system” as used herein can refer to a single device, multiple devices, etc. Storage resources or other memory can be internal or external to the respective devices with which they are associated. The storage resources can include any one or more of volatile or non-volatile memory, hard drives, flash storage devices, and/or optical storage devices (e.g., CDs, DVDs, etc.), among others. As used herein, the term “computer-readable medium” can include signals. In contrast, the term “computer-readable storage medium” excludes signals.

Memory as described herein may include one or more non-transitory, tangible, computer-readable, and/or computer-executable storage media. Examples of memory include computer memory (for example, Random Access Memory (RAM) or Read Only Memory (ROM), mass storage media (for example, a Compact Disk (CD) or a Digital Video Disk (DVD)), database, and/or network storage (for example, a server), and/or other computer-readable medium. Computer-readable storage media includes computer-readable storage devices. Examples of computer-readable storage devices include volatile storage media, such as RAM, and non-volatile storage media, such as hard drives, optical discs, and flash memory, among others.

In some cases, the devices are configured with a general-purpose hardware processor and storage resources. In other cases, a device can include a system on a chip (SOC) type design. In SOC design implementations, functionality provided by the device can be integrated on a single SOC or multiple coupled SOCs. One or more associated processors can coordinate with shared resources, such as memory, storage, etc., and/or one or more dedicated resources, such as hardware blocks perform certain specific functionality. Thus, the term “processor,” “hardware processor” or “hardware processing unit” as used herein can also refer to central processing units (CPUs), graphical processing units (GPUs), controllers, microcontrollers, processor cores, or other types of processing devices suitable for implementation both in conventional computing architectures as well as SOC designs.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

In some configurations, any of the modules/code described herein can be implemented in software, hardware, and/or firmware. In any case, the modules/code can be provided during manufacture of the device or by an intermediary that prepares the device for sale to the end user. In other instances, the end user may install these modules/code later, such as by downloading executable code and installing the executable code on the corresponding device.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is configured to perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail, power supply rail, or more simply a “rail,” may also be referred to as a voltage terminal and may generally mean a common node or set of coupled nodes in a circuit at the same potential.

What is claimed is:

1. A system, comprising:
a charging device cable of being coupled to a power supply rail, wherein the charging device includes a controller cable of:
receiving a plurality of voltage measurements of a voltage discharge of a capacitor that is positioned between a power supply rail and ground;
determining a predicted settling voltage based on the plurality of voltage measurements, wherein the predicted settling voltage is a voltage level at which the voltage discharge is predicted to stabilize; and
outputting an insulation resistance present between the power supply rail and the ground; and
a load capable of receiving power from the charging device.

2. The system of claim 1, wherein the controller is further configured to determine the predicted settling voltage based on a capacitor discharge function that corresponds to a decay of the voltage discharge over time.

3. The system of claim 1, wherein the insulation resistance is a first insulation resistance measurement, the power supply rail is a first power supply rail, and the controller is further configured to determine a second insulation resistance measurement corresponding to a second power supply rail in electrical communication with the controller.

4. The system of claim 3, wherein the plurality of voltage measurements is a first plurality of voltage measurements, the voltage discharge is a first voltage discharge, the capacitor is a first capacitor, the predicted settling voltage is a first predicted settling voltage, and the controller is further configured to:
receive a second plurality of voltage measurements of a second voltage discharge of a second capacitor positioned between the second power supply rail and the ground; and
provide a second predicted settling voltage based on the second plurality of voltage measurements.

5. The system of claim 4, wherein the controller is further configured to determine an insulation capacitance of the first power supply rail based on the first and second insulation resistance measurements.

6. The system of claim 5, wherein the controller is further configured to determine a time constant of the capacitor by calculating a derivative of a discharge curve of the capacitor at a time of a voltage measurement of the plurality of voltage measurements.

7. The system of claim 1, wherein the power supply rail is a first power supply rail, and further comprising a voltage divider circuit that includes first and second voltage branches, wherein the first voltage branch is coupled to the first power supply rail and includes first and second resistors coupled in series, wherein the second voltage branch is coupled to a second power supply rail and includes third and fourth resistors connected in series.

8. The system of claim 7, wherein the capacitor is a first capacitor, and wherein the first capacitor is coupled in parallel to the first resistor, further comprising a second capacitor that is coupled in parallel to the third resistor.

9. The system of claim 7, further comprising a first switch coupled to the first voltage branch and a second switch coupled to the second voltage branch, wherein the controller closes the first switch and opens the second switch while receiving the plurality of voltage measurements.

10. The system of claim 9, wherein the plurality of voltage measurements comprises a first plurality of voltage measurements, and wherein the controller opens the first switch and closes the second switch while receiving a second plurality of voltage measurements.

11. The system of claim 1, wherein the controller is further configured to initiate an alert responsive to the insulation resistance exceeding a threshold.

12. The system of claim 1, wherein the plurality of voltage measurements includes first, second, and third voltage measurements, wherein a first interval spanning between the first and second voltage measurements is half the length of a second interval spanning between the first and third voltage measurements.

13. The system of claim 1, wherein the controller is configured to determine the insulation resistance based on four-function arithmetic.

14. An apparatus, comprising:
a power supply rail capable of being coupled to a power source; and
a controller capable of:
receiving a plurality of voltage measurements of a voltage discharge of a capacitor that is positioned between the power supply rail and a ground;
determining a time constant of the capacitor based on plurality of voltage measurements;
determining a capacitance of the capacitor based on the time constant; and
outputting the capacitance.

15. The apparatus of claim 14, wherein the capacitor is a Y-type capacitor.

16. The apparatus of claim 14, wherein the time constant is determined by calculating a derivative of a point along a discharge curve comprised of the plurality of voltage measurements.

17. The apparatus of claim 14, wherein the controller is further configured to:
determine a predicted settling voltage based on the plurality of voltage measurements, wherein the predicted settling voltage is a voltage level at which the voltage discharge is predicted to stabilize; and
output an insulation resistance measurement present between the power source and ground.

18. A computer program product to monitor an insulation resistance of a power supply circuit, the computer program product including a computer-readable storage medium having computer-readable program code embodied therewith, the computer-readable program code to be executed by a controller to:
receive a plurality of voltage measurements of a voltage discharge of a capacitor that is positioned between a power supply rail and ground;
determine a predicted settling voltage based on the plurality of voltage measurements, wherein the predicted settling voltage is a voltage level at which the voltage discharge is predicted to stabilize; and
output an insulation resistance present between the power supply rail and the ground.

19. The computer program product of claim 18, wherein the computer-readable program code is further executable by the controller to determine the predicted settling voltage based on a capacitor discharge function that corresponds to a decay of the voltage discharge over time.

20. The computer program product of claim 18, wherein the plurality of voltage measurements comprises a first plurality of voltage measurements, and wherein the computer-readable program code is further executable by the controller to open a first switch and close a second switch while receiving a second plurality of voltage measurements.
